(19) United States
(12) Patent Application Publication
(10) Pub. No.: US 2010/0291488 A1
(43) Pub. Date: Nov. 18, 2010

(54) Manufacturing method for multilayer core board

(75) Inventors: Soon-Oh Jung, Seoul (KR); Cheol-Ho Choi, Suwon-si (KR); Chang-Hyun Nam, Cheongju-si (KR); Hong-Won Kim, Suwon-si (KR); Seung-Chul Kim, Cheongju-si (KR)

Correspondence Address: STAAS & HALSEY LLP, SUITE 700, 1201 NEW YORK AVENUE, N.W., WASHINGTON, DC, 20005, US

(73) Assignee: SAMSUNG ELECTRO-MECHANICS CO., LTD., Suwon (KR)

(21) Appl. No.: 12/805,371

(22) Filed: Jul. 27, 2010

Related U.S. Application Data
(62) Division of application No. 11/708,577, filed on Feb. 21, 2007.

(30) Foreign Application Priority Data
Feb. 24, 2006 (KR) 10-2006-0018241

(51) Int. Cl. H05K 13/00; B05D 5/12; G03F 7/20

(52) U.S. Cl. 430/314; 29/829; 427/99.5

(57) ABSTRACT

A method for manufacturing a cone board including: preparing a core insulation layer including one or more resins selected from the group consisting of epoxy resins and bismaleimide triazine resins; and forming a first nickel layer on at least one surface of the core insulation layer by electroless plating

### CROSS-REFERENCE TO RELATED APPLICATIONS

This application is a U.S. divisional application filed under 37 CFR 1.53 (b) claiming priority benefit of U.S. Ser. No. 11/708,577 filed in the United States on Feb. 21, 2007, which claims earlier priority benefit to Korean Patent Application No. 10-2006-0018241 filed with the Korean Intellectual Property Office on Feb. 24, 2006, the disclosures of which are incorporated herein by reference.

### BACKGROUND

1. Field

The present invention relates to a board and a manufacturing method thereof, and more particularly, to a board having excellent joining strength between an insulation layer and a conductive layer, and a manufacturing method thereof.

2. Description of the Related Art

As electric components become much smaller, thinner, lighter, and more efficient, there is an increasing demand for component materials providing the corresponding performances. Boards as such a component material should satisfy high densification, thin plating, miniaturization, packaging, and the like and particularly, researches on a variety of kinds of boards used in highly integrated components have been extensively conducted to satisfy such requirements.

In general printed circuit boards, a copper clad laminate(CCL), which has a copper foil layer stacked on at least one surface of an epoxy resin layer, has been used as a core board. However, since binding strength between a copper foil layer and an insulation layer forming the CCL is weak due to thick thickness of the copper foil layer of CCL, it is not suitable to efficiently apply the semi-additive method. In order to form fine circuits has costly Animoto build-up film(ABF) been used, and it is thus not suitable to use as core materials.

Further, with such developments on high integration and thin plating is there demand to provide insulation layers having high glass transition temperature to implement high electric performances. To this end, some additives such as flame-retardant materials or fillers are added into the insulation layer. However, binding strength towards conductive layers gets weaker with more using of such additives.

Accordingly, there has been demand for new materials not only having high glass transition temperature but also improved binding strength between the insulation layer and the conductive layer to form fine circuit patterns. In order to resolve these problems, employing of costly equipments for plasma treatment or sputtering, mechanical methods, and chemical methods have been introduced. However, there is still no solution to improve the binding strength of the conductive layer. Therefore, there are in dire need of developing new methods to improve the binding strength between the insulation layer and the conductive layer and thus to form fine wirings on inner layer circuits or outer layer circuits.

### SUMMARY

The present invention provides a core board and a manufacturing method thereof, in which the core board includes a nickel layer as a seed layer to improve the binding strength between an insulation layer and a conductive layer, so that it allows forming fine inner circuits by the semi-additive method.

The present invention further provides a core board and a manufacturing method thereof, in which a plating time is 10% of that conducted by the conventional electroless copper plating, forming much thinner nickel plating layers is possible, etching selectively on nickel layer is possible during the flash etching process, etching time is reduced, and occurrence of dangerous under cut is reduced.

The present invention further provides a multilayer board and a manufacturing method thereof, in which the binding strength between an insulation layer and the conductive layer such as a copper layer as well as a core board is improved to form fine circuits, plating time and plating thickness are reduced, selective etching is made during the flash etching process to allow reduction of etching time, and occurrence of dangerous under cut is reduced.

The present invention still further provides a core board, a multilayer board and their manufacturing methods, in which fine circuits are formed directly on the core board, so that a number of stacked layers are reduced, a thickness of the nickel conductive layer is reduced, so that the board becomes thinner, productivity is improved, and manufacturing cost is reduced.

The present invention still further provides a core board, a multilayer board and their manufacturing methods, in which sodium hypophosphate is used, instead of formalin used as a reducing agent in the electroless copper plating which has no harm on human beings and reduces environmental pollution, plating time is 10% of that conducted by the conventional method, and manufacturing cost is reduced.

The present invention still further provides a core board, a multilayer board and their manufacturing methods, in which a nickel layer functions as a thin layer between an insulation layer and a conductive layer such as a copper layer to prevent deterioration of resins caused by metals or metal oxides composed the conductive layer, to improve the reduction of insulation ability associated with discoloration of resins which is caused by metal migration into the resins in conventional methods, and to increase the binding strength with the conductive layers.

According to an embodiment, the present invention provides a core board including a core insulation layer including one or more resins selected from the group consisting of epoxy resins and bismaleimide triazine resins, and a first nickel layer stacked on at least one surface of the core insulation layer.

The core insulation layer may include a reinforcement material of glass fiber and the first nickel layer may have a thickness of 0.3-2 μm. The first nickel layer may be added by 5-15 parts by weight with respect to 100 parts by weight of the total layers and the binding strength between the core insulation layer and the first nickel layer may be in the range of from 0.7 to 0.9 kgf/cm. The core board may further include a first copper layer stacked on the first nickel layer.

According to another embodiment, the present invention provides a multilayer board including a core board on which inner circuits are formed according to wiring patterns; a first insulation layer including one or more resins selected from the group consisting of epoxy resins and bismaleimide triazine resins, on the core board; a second nickel layer stacked on the first insulation layer according to the wiring patterns; and a second copper layer stacked on the second nickel layer.

Here, the core board may include a core insulation layer including one or more resins selected from the group consisting of epoxy resins and bismaleimide triazine resins; a first nickel layer stacked on at least one surface of the core insulation layer according to the wiring patterns; and a first copper layer stacked on the first nickel layer.

A wiring distance between the first nickel layer and the first copper layer is 10-20 μm and the second nickel layer has a thickness of 0.3-2 μm. The second nickel layer is added by 5-15 parts by weight with respect to 100 parts by weight of the total layers. The binding strength between the first insulation layer and the second nickel layer is in the range of from 0.7 to 0.9 kgf/cm and a wiring distance between the second nickel layer and the second copper layer is 10-20 μm.

According to another embodiment, the present invention provides a method for manufacturing a core board, including: preparing a core insulation layer including one or more resins selected from the group consisting of epoxy resins and bismaleimide triazine resins; and forming a first nickel layer on at least one surface of the core insulation layer by the electroless plating.

Here, the electroless plating is performed by using a plating bath including a nickel salt, a sodium hypophosphate, and a pH controlling agent. The nickel salt is one or more compounds selected from the group consisting of nickel sulfate, nickel chloride, nickel fluoborate, and nickel amidosulfonate. The nickel salt is added by 4-250 g/L and the sodium hypophosphate is added by 20-700 g/L. The pH controlling agent is one or more compounds selected from the group consisting of ammonia water, hydrochloric acid, and acetic acid and pH of the plating bath is 4-6. The plating bath further includes a complexing agent. The complexing agent is succinic acid and the succinic acid is added by 5-50 g/L. A temperature of the plating bath is 60-90° C. and the electroless plating is performed for 1-10 min.

Here, the first nickel layer has a thickness of 0.3-2 μm and is added by 5-15 parts by weight with respect to 100 parts by weight of the total layers.

The method may further include stacking a first photo-resist layer on the first nickel layer, exposing and developing the first photo-resist layer in correspondence with wiring patterns, forming a first copper layer on the first nickel layer by the electro plating, removing the first photo-resist layer, and etching the first nickel layer. A wiring distance between the first nickel layer and the first copper layer is 10-20 μm.

According to another embodiment, the present invention provides a method for manufacturing a multilayer board, the method including: forming circuits according to wiring patterns on a core board; stacking a first insulation layer including one or more resins selected from the group consisting of epoxy resins and bismaleimide triazine resins on at least one surface of the core board; forming a second nickel layer on the first insulation layer by the electroless plating; stacking a second photo-resist layer on the second nickel layer; exposing and developing the second photo-resist layer in correspondence with the wiring patterns; forming a second copper layer on the second nickel layer by the electro plating; removing the second photo-resist layer; and etching the first nickel layer.

The electroless plating is performed by using a plating bath including a nickel salt, a sodium hypophosphate, and a pH controlling agent. The nickel salt is one or more compounds selected from the group consisting of nickel sulfate, nickel chloride, nickel fluoborate, and nickel amidosulfonate and added by 4-250 g/L. The sodium hypophosphate is added by 20-700 g/L and the pH controlling agent is one or more compounds selected from the group consisting of ammonia water, hydrochloric acid, and acetic acid. The pH of the plating bath is 4-6 and the plating bath further includes a complexing agent. Here, the complexing agent is succinic acid and the succinic acid is added by 5-50 g/L. The temperature of the plating bath is 60-90° C. and the electroless plating is performed for 1-10 min.

The second nickel layer has a thickness of 0.3-2 μm and is added by 5-15 parts by weight with respect to 100 parts by weight of the total layers.

Additional aspects and advantages of the present general inventive concept will be set forth in part in the description which follows, and in part will be obvious from the description, or may be learned by practice of the general inventive concept.

### BRIEF DESCRIPTION OF THE DRAWINGS

FIGS. 1 and 2 are cross-sectional views of a core board according to an embodiment of the present invention.

FIG. 3 is a cross-sectional view of a multilayer board according to an embodiment of the present invention.

FIG. 4 is a flow diagram illustrating a process of manufacturing a core board according to an embodiment of the present invention.

FIG. 5 is a flow diagram illustrating a process of manufacturing a multilayer board according to an embodiment of the present invention.

FIGS. 6 to 8 represent results of peel strength(binding strength) tests according to embodiments of the present invention and according to comparison examples.

### DESCRIPTION OF EMBODIMENTS

Embodiments of the boards and manufacturing method thereof, according to aspects of the invention, will be described below in more detail with reference to the accompanying drawings. Here, a core board including an electroless nickel plating layer and a multilayer board including an electroless nickel plating layer are described separately but a method for forming the nickel layer by the electroless plating is same.

A core board of the present invention is a basic board to form a multilayer board by stacking insulation layers and conductive layers in order on one or both surfaces thereof. Such a core board is required to have a particular strength and copper clad laminate(CCL) has been usually used as a core board. However, a core board of the present invention includes a nickel layer and thus, it allows forming fine circuits on the core board by the semi-additive method.

When fine circuits are formed on the core board or the multilayer board by the semi-additive method, an electroless nickel plating layer may be included in the present invention, instead of conventional electroless copper plating layer.

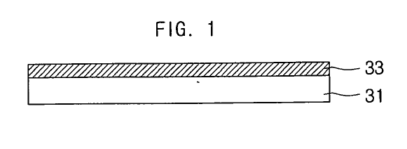

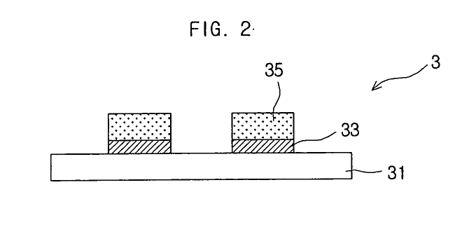

FIGS. 1 and 2 are cross-sectional views of a core board according to an embodiment of the invention. Referring to FIG. 1, the core board of the invention may include a core insulation layer 31 and a first nickel layer 33 and referring to FIG. 2, the core board may include a core insulation layer 31, a first nickel layer 33 formed according to circuit patterns, and a first copper layer 35. The core insulation layer may include one or more resins selected from the group consisting of epoxy resins and bismaleimide triazine resins. When the nickel layer is formed on the conductive layer by electro plating, it acts as a seed layer, so that it improves binding strength between the conductive layer and the core insulation layer. Not only a thickness of the seed layer is reduced by 20-50%, compared to that of the conventional copper seed layer but also the binding strength is increased by more than 300-400%

The core insulation layer 31 may be any typical core insulation layer including one or more resins chosen from epoxy resins and bismaleimide triazine resins. The core insulation layer may further include a reinforcement material or a filler to provide strength, a flame retardant agent to provide flame retardancy, or any additive, within a scope apparent to those skilled in the art. According to an embodiment of the invention, glass fiber as a reinforcement material is added into the core insulation layer.

A thickness of the nickel layer may be in the range of from 0.3 to 2 μm, preferably from 0.4 to 1 μm. If the thickness is less than 0.3 μm, the peel strength to the core insulation layer deteriorates and if it is greater than 2 μm, efficiency becomes lowered. The nickel layer is included by 5-15 parts by weight, preferably 7-12 parts by weight, with respect to 100 parts by weight of the total layers. Phosphorus is supplied from sodium hypophosphate, which is a reducing agent, used in an electroless plating bath in order to form the nickel layer. Phosphorus may improve the strength of the nickel layer.

The binding strength between the core insulation layer and the nickel layer of the core board manufactured according to the method of the present invention was determined by universal testing machine(UTM) and the result showed the binding strength of about 0.7-0.9 kgf/cm. On the other hand, when conventional electroless copper plating was performed, the binding strength was about 0.1 kgf/cm, much lower than even 0.5 kgf/cm. It is noted that the binding strength in the present invention is by far improved

The core board may further include a first copper layer 35, which may be formed by typical electro plating and inner circuits may be formed on the first nickel layer 31 and the first copper layer 35 by the typical semi-additive method. That is, a method to form a plating layer having a desired thickness by the electro plating after forming a seed layer by the electroless plating may be applied to form fine wirings having a wiring distance of 20 μm or less, preferably 10-20 μm. However, when a copper clad laminate(CCL) is used as a core board, there is limit to apply the semi-additive method due to the thickness of the copper layer.

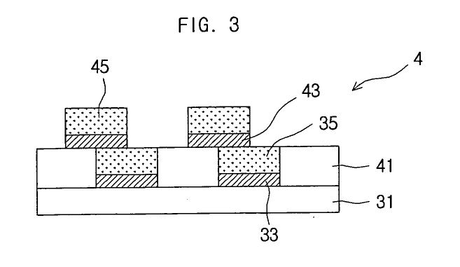

FIG. 3 is a cross-sectional view of a multilayer board according to an embodiment of the present invention. Referring to FIG. 3, a multilayer board 4 includes a first insulation layer 41 formed on a core board 3 on which inner circuits are formed according to wiring patterns, a second nickel layer 43 stacked on the first insulation layer according to the wiring patterns, and a second copper layer 45 stacked on the second nickel layer. Here, the first insulation layer 41 includes one or more resins chosen from epoxy resins and bismaleimide triazine resins.

According to an embodiment of the invention, the core board 3 included in the multilayer board 4 may be a core board including fine wirings described above. That is, the core board may include a core insulation layer 31, a first nickel layer 33 stacked on at least one surface of the core insulation layer 31 according to the wiring patterns, and a first copper layer 35 stacked on the first nickel layer 33. A wiring distance of such a produced core board may be 20 μm or less, preferably 10-20 μm.

The second nickel layer may also form wirings by the semi-additive method as the first nickel layer and a conductive layer such as the second copper layer may be formed thereon. Such a stacking process, first stacking a nickel layer on an insulation layer which is a seed layer, and then stacking a copper layer, is repeated to form a multilayer board having a desired number of layers. A thickness of the nickel layer, phosphorus content, physical properties such as binding strength with an insulation layer are already described in the description of the nickel layer on the core board and thus further description will be omitted.

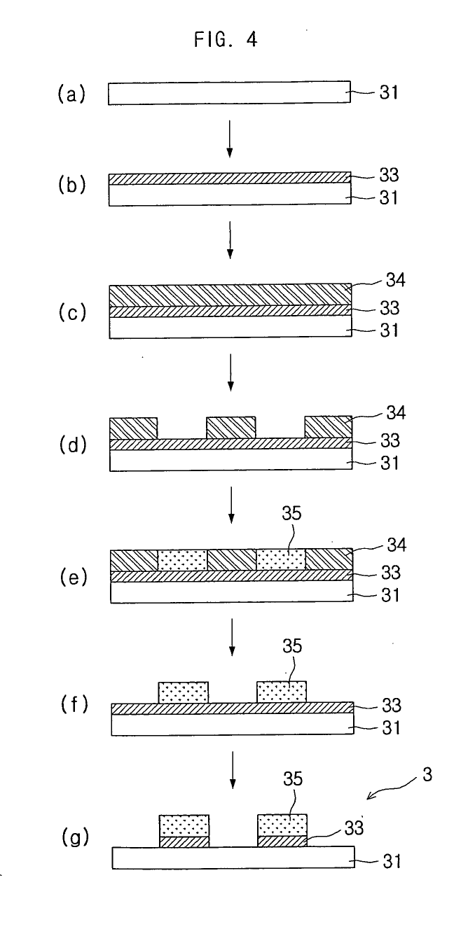

FIG. 4 is a flow diagram illustrating a process for manufacturing a core board according to an embodiment of the present invention. Referring to FIG. 4, the method for manufacturing a core board includes: preparing a core insulation layer including one or more resins selected from the group consisting of epoxy resins and bismaleimide triazine resins; and forming a first nickel layer on at least one surface of the core insulation layer by the electroless plating. The electroless plating may be performed by using any typical nickel plating bath, known to those skilled in the art.

The method for manufacturing the core board may further include the following processes to form wirings on the first nickel layer stacked by the electroless plating: stacking a first photo-resist layer on the first nickel layer stacked by the electroless plating; exposing and developing the first photo-resist layer in correspondence with wiring patterns; forming a first copper layer on the first nickel layer where the first photo-resist layer is not stacked by the electro plating; removing the first photo-resist layer; and etching the first nickel layer. Wirings having a wiring distance of 10-20 μm are formed on the core board prepared by the described method. Hereinafter, the nickel plating bath is described but it is not limited to these cases.

According to an embodiment of the present invention, the nickel layer may be formed by employing a plating bath including nickel salt, sodium hypophosphate, and a pH controlling agent. Here, the nickel salt may be one or more compounds selected from the group consisting of nickel sulfate, nickel chloride, nickel fluoborate, and nickel amidosulfonate and added by 4-250 g/L. When the concentration of the nickel salt is lower than 4 g/L, it is difficult to obtain a desired thickness and a plating rate decreases. On the other hand, when it is greater than 250 g/L, although a plating rate increases, the plating bath can be decomposed, resulting in causing high defective rate and efficiency is deteriorated.

The sodium hypophosphate used as a reducing agent in the present invention is added by 20-700 g/L, which is an appropriate concentration to form a nickel layer having a thickness of 0.3-2 μm. If the concentration of the sodium hypophosphate is lower than 20 g/L, a reaction rate becomes too slow, while if it is greater than 700 g/L, a reaction rate becomes too fast and thus, the plating solution can be decomposed. In the conventional copper electroless plating, formalin has been used as a reducing agent but it is restrictive in use since it harms human beings and causes environmental pollution. However, the sodium hypophosphate, which does not harm human beings, is used to manufacture boards in the present invention.

The pH controlling agent is one or more compounds selected from the group consisting of ammonia water, hydrochloric acid, and acetic acid and pH of the plating bath is 4-6, preferably 4.2-4.8. Not only the plating rate is fast but the plating becomes effective in this range of pH. For example, when ammonia water is used as a base in the plating process, an acetic acid may be used as a buffering agent to prevent rapid reduction of pH of the plating solution.

The plating bath may further include a complexing agent to prevent from self-decomposition by controlling a plating rate. Succinic acid is used in the present invention and a concentration is in the range of from 5 to 50 g/L. When the concentration is less than 5 g/L, since large volume of nickel are not complexed, resulting in deteriorate plating, while when it is greater than 50 g/L, the plating solution becomes stable but a plating rate is lowered.

Any additional additive such as a stabilizing agent or an accelerating agent may be selectively added, within a scope apparent to those skilled in the art. For example, lead chlorides (LAT) as a stabilizing agent may be used to decrease a plating rate and thus prevent from decomposition of a plating solution. Here, 1-3 ppm of the stabilizing agent may be added. If it is added more than 3 ppm, a plating reaction stops and thus, plating is partially performed. On the other hand, if it is less than 1 ppm, it is not functioning as a stabilizing agent. Fluorides and/or sulfides as an accelerating agent may further be added to increase amount of precipitation within same time. Here, 1-3 ppm of the accelerating agent may be added. If it is added more than 3 ppm, self-decomposition may occur. On the other hand, if it is less than 1 ppm, it is not effective.

A temperature of the plating bath may be 60-90° C. since when the temperature is lower than 60° C., a plating rate becomes slower and when it is higher than 90° C., precipitation is not uniformly formed. The plating time may be 1-10 min, preferably 2-4 min, which is only 10% of that taken by conventional electroless plating. Thus, the manufacturing time may be reduced.

According to another embodiment of the present invention, nickel salt, a reducing agent and a complexing agent as main ingredients of a nickel plating bath may be used. 40-150 g/L of Na₃C₆H₅O₇, NaCO₂CH₃, hydrazine, or borane as the reducing agent may be added. 40-150 g/L of sodium hypophosphate(NaH₂PO₂) as the complexing agent may be added. 12-220 g/L of nickel sulfate or nickel chloride as the nickel salt may be added. Further, a small amount of PbNO3 as a stabilizing agent may be added. Here, pH of the plating bath may be 4-6 for an acid bath and 8-10 for an alkali bath. A pH controlling agent in the alkali bath may be ammonia water and that in the acid bath may be hydrochloric acid.

By employing the plating method described above is prepared a nickel layer having 5-15 parts by weight of phosphorus. A thickness of the nickel layer is 0.3-2 μm which satisfies a required thickness as a seed layer and the binding strength between the nickel layer and the insulation layer is improved which thus allows manufacturing the thinner nickel seed layer, compared to the conventional copper layer. Further, in the etching process, which is performed after manufacturing electroless plating layer, an etching time may be reduced. In addition, since compositions in the seed layer and the conductive layer such as a copper layer formed on the seed layer are different each other, selective etching on the nickel layer is possible, so that the it prevents from weakening of the binding strength between the insulation layer and the conductive layer due to reduced occurrence of under cut.

The nickel layer may prevents deterioration of resins by metals or metal oxides in the conductive layer by functioning as a thin layer between the insulation layer and the conductive layer and may also improve the insulation ability and the binding strength with the conductive layer by preventing decoloration of resins.

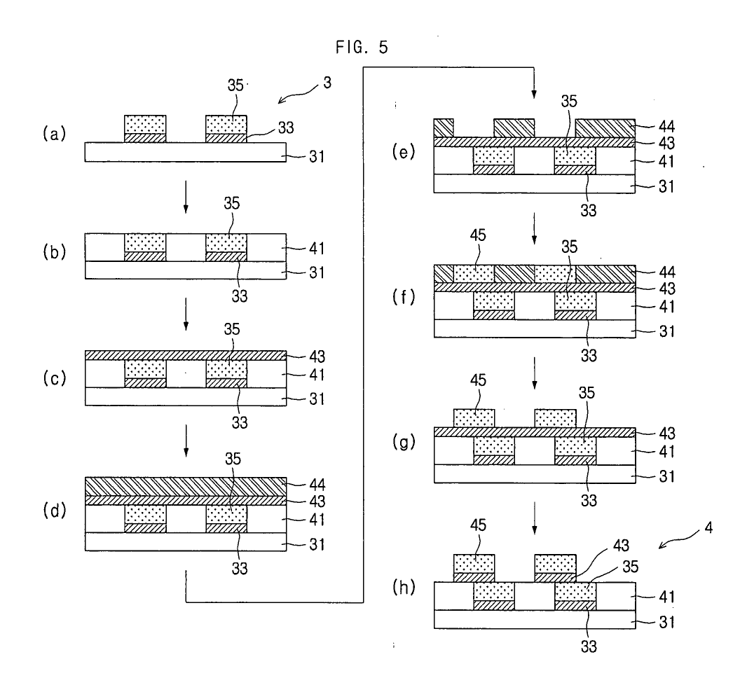

FIG. 5 is a flow diagram illustrating a process for manufacturing a multilayer board according to an embodiment of the present invention. Referring to FIG. 5, the method for manufacturing a multilayer board includes: forming circuits according to wiring patterns on a core board; stacking a first insulation layer including one or more resins selected from the group consisting of epoxy resins and bismaleimide triazine resins; forming a second nickel layer on the first insulation layer by the electroless plating; stacking a second photo-resist layer on the second nickel layer; exposing and developing the second photo-resist layer in correspondence with the wiring patterns; forming a second copper layer on the second nickel layer by the electro plating; removing the second photo-resist layer; and etching the second nickel layer where the second copper layer is not stacked.

Here, the core board is prepared by the method described above. The electroless plating to form the second nickel layer is the same as that to form the first nickel layer and thus detailed description is omitted.

Pretreatment processes for the electroless plating are not limited, within a scope apparent to those skilled in the art. Examples of such pretreatment processes may include conditioning treatment, pre-dip treatment, acceleration treatment, treatment with a reduction agent, and the like.

The nickel layer of the present invention may be properly applied to the insulation layer including one or more resins chosen from epoxy resins and bismaleimide triazine resins(BT-resins). Such resins are generally used for rigid boards and contain additives to increase rigidity which causes poor binding to conductive layers. An insulation layer is usually made of a mixture of various kinds of resins according to its desired property, instead of using a single kind of resin. Generally, a mixture of a various kinds of epoxy resins or an epoxy resin modified by adding bismaleimide triazine resin to a base epoxy resin is used.

### EXAMPLE

| | | | | Sodium | | | |
|---|---|---|---|---|---|---|---|
| | Temp | Road | Nickel | hypophosphate | Succinic | | Time |
| | (° C.) | (dm²/L) | sulfate(g/L) | (g/L) | acid(g/L) | pH | (min) |
| Plating | 75-90 | 0.1-1 | 4-4.8 | 20-50 | 5-30 | 4.2-4.8 | 2-4 |
| conditions | | | | | | | |

After a nickel plating layer having a thickness of 0.4-1 μm was formed on glass epoxy laminate(FR-4) by the above plating conditions three times, each peel strength was determined. The result is summarized in Table 1. A nickel plating layer having a thickness of 0.4-1 μm was also formed on BT-resin by the same plating conditions and its peel strength was determined. The result is summarized in Table 1. It is noted that the peel strength of the nickel plating layer is superior to that of the electroless copper plating layer.

### Comparison Example

| | | | | 37% | | | |
|---|---|---|---|---|---|---|---|
| | Temp | Road | Copper | formalin | Sodium | | Time |
| | (° C.) | (dm²/L) | sulfate(g/L) | (g/L) | hydroxide(g/L) | pH | (min) |
| Plating | 30-36 | 0.2-1 | 8-12 | 10-30 | 5-30 | 12-13 | 20-30 |
| conditions | | | | | | | |

A copper plating layer was formed on the same resin used in Example by the above plating conditions and the peel strength was determined. The result is summarized in Table 1.

TABLE 1
Peel strength(kgf/cm)

| Insulation layer | | FR-4 | FR-4 | FR-4 | BT-resin |
|---|---|---|---|---|---|
| Seed layer | Copper | Comp. Ex. 1 | Comp. Ex. 2 | Comp. Ex. 3 | Comp. Ex. 4 |
| | plating layer | 0.1 | 0.2 | 0.5 | 0.5 |
| | Nickel | Ex. 1 | Ex. 2 | Ex. 3 | Ex. 4 |
| | plating layer | 0.8 | 0.8 | 0.9 | 0.75 |

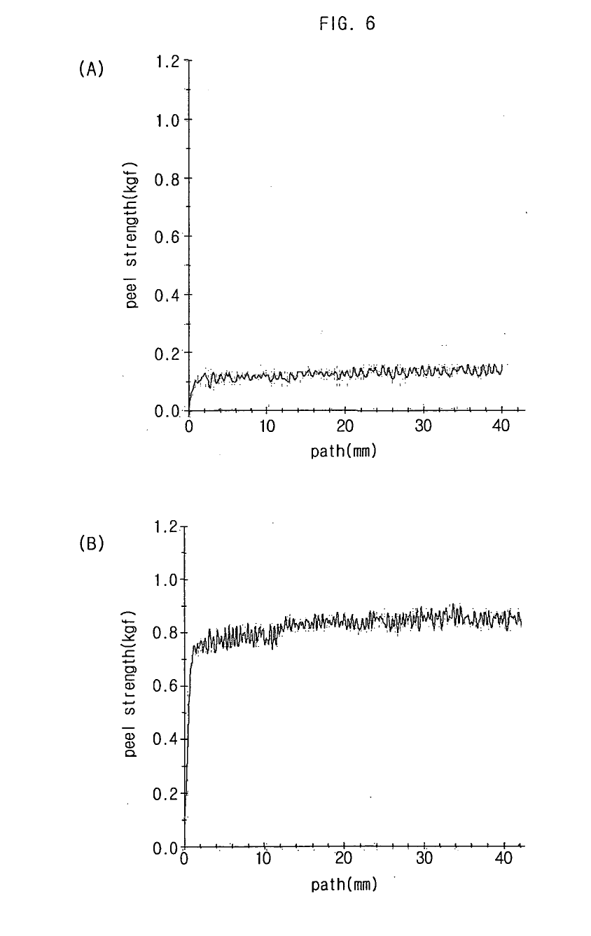

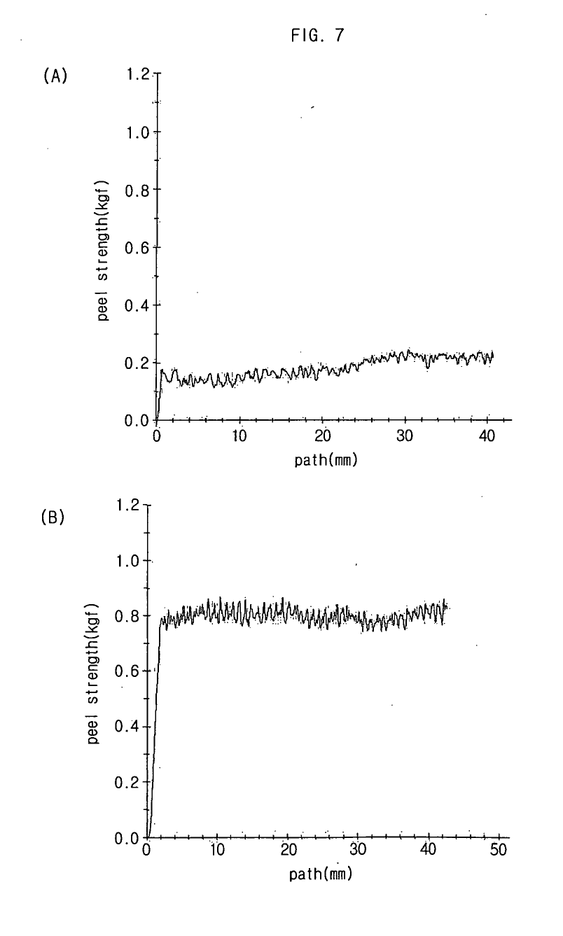

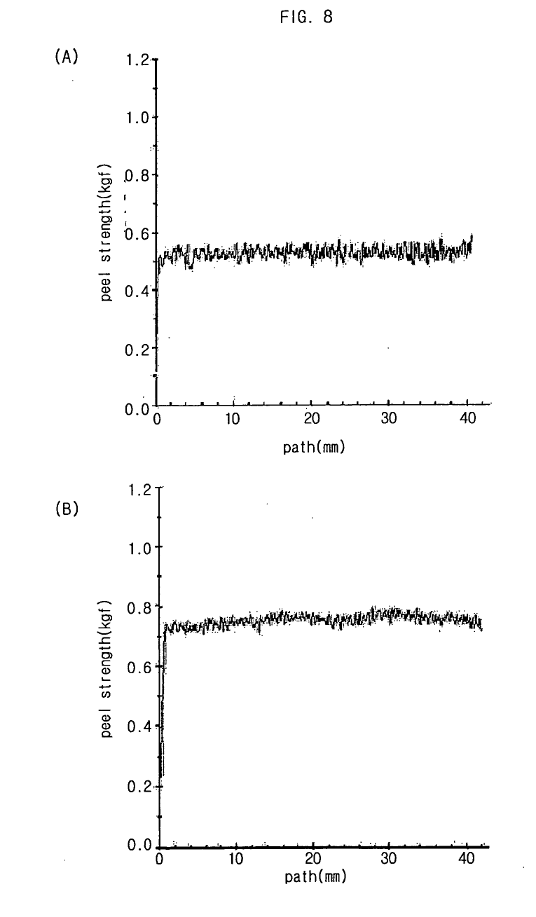

FIGS. 6-8 represent results of peel strength tests according to embodiments of the present invention and according to comparison examples. FIG. 6A is a graph of the peel strength of the copper layer prepared by comparison example 1, FIG. 6B is a graph of the peel strength of the nickel layer prepared by example 1. FIG. 7A is a graph of the peel strength of the copper layer prepared by comparison example 2, FIG. 7B is a graph of the peel strength of the nickel layer prepared by example 2. FIG. 8A is a graph of the peel strength of the copper layer prepared by comparison example 4, FIG. 8B is a graph of the peel strength of the nickel layer prepared by example 4.

As shown in FIGS. 6 to 8, it is noted that the peel strength(or binding strength) between the insulation layer and the nickel layer is in the range of from 0.7 to 0.9 kgf/cm which is 0.5 to 5 times stronger than that between the insulation layer and the copper layer.

Accordingly, the present invention provides a core board and a method for manufacturing the core board, which allows producing fine inner circuits on a core board by the semi-additive method, by including a nickel layer as a seed layer to improve the binding strength between a core insulation layer and a conductive layer such a copper layer. The present invention also provides a core board and a method for manufacturing the core board, where plating time is about 10% of that taken by the conventional electroless copper plating, it allows forming much thinner electroless nickel plating layer, selective etching on nickel layer is possible during the flash etching, the etching time is reduced, and occurrence of under cut is reduced.

While the spirit of the invention has been described in detail with reference to particular embodiments, the embodiments are for illustrative purposes only and do not limit the invention. It is to be appreciated that those skilled in the art can change or modify the embodiments without departing from the scope and spirit of the invention.

What is claimed is:

1. A method for manufacturing a core board, the method comprising:
preparing a core insulation layer including one or more resins selected from the group consisting of epoxy resins and bismaleimide triazine resins; and
forming a first nickel layer on at least one surface of the core insulation layer by electroless plating.

2. The method of claim 1, wherein the electroless plating is performed by using a plating bath including a nickel salt, a sodium hypophosphate, and a pH controlling agent.

3. The method of claim 2, wherein the nickel salt is one or more compounds selected from the group consisting of nickel sulfate, nickel chloride, nickel fluoborate, and nickel amidosulfonate.

4. The method of claim 2, wherein the nickel salt is added by 4-250 g/L.

5. The method of claim 2, wherein the sodium hypophosphate is added by 20-700 g/L.

6. The method of claim 2, wherein the pH controlling agent is one or more compounds selected from the group consisting of ammonia water, hydrochloric acid, and acetic acid.

7. The method of claim 2, wherein pH of the plating bath is 4-6.

8. The method of claim 2, wherein the plating bath further includes a complexing agent.

9. The method of claim 8, wherein the complexing agent is succinic acid and the succinic acid is added by 5-50 g/L.

10. The method of claim 2, wherein a temperature of the plating bath is 60-90° C.

11. The method of claim 2, wherein the electroless plating is performed for 1-10 min.

12. The method of claim 1, wherein the first nickel layer has a thickness of 0.3-2 μm.

13. The method of claim 1, wherein the first nickel layer is added by 5-15 parts by weight with respect to 100 parts by weight of the total layers.

14. The method of claim 1, the method further comprising:
stacking a first photo-resist layer on the first nickel layer;
exposing and developing the first photo-resist layer in correspondence with wiring patterns;
forming a first copper layer on the first nickel layer by the electro plating;
removing the first photo-resist layer; and
etching the first nickel layer.

15. The method of claim 14, wherein a wiring distance between the first nickel layer and the first copper layer is 10-20 μm.

16. A method for manufacturing a multilayer board, the method comprising:
forming circuits according to wiring patterns on a core board;
stacking a first insulation layer including one or more resins selected from the group consisting of epoxy resins and bismaleimide triazine resins;
forming a second nickel layer on the first insulation layer by the electroless plating;
stacking a second photo-resist layer on the second nickel layer;
exposing and developing the second photo-resist layer in correspondence with the wiring patterns;
forming a second copper layer on the second nickel layer by the electro plating;
removing the second photo-resist layer; and
etching the second nickel layer.

17. The method of claim 16, wherein the core board is the core board manufactured by the method of
preparing a core insulation layer including one or more resins selected from the group consisting of epoxy resins and bismaleimide triazine resins;
forming a first nickel layer on at least one surface of the core insulation layer by the electroless plating;
stacking a first photo-resist layer on the first nickel layer;
exposing and developing the first photo-resist layer in correspondence with wiring patterns;
forming a first copper layer on the first nickel layer by the electro plating;
removing the first photo-resist layer; and
etching the first nickel layer.

18. The method of claim 16, wherein the electroless plating is performed by using a plating bath including a nickel salt, a sodium hypophosphate, and a pH controlling agent.

19. The method of claim 18, wherein the nickel salt is one or more compounds selected from the group consisting of nickel sulfate, nickel chloride, nickel fluoborate, and nickel amidosulfonate.

20. The method of claim 18, wherein the nickel salt is added by 4-250 g/L.

21. The method of claim 18, wherein the sodium hypophosphate is added by 20-700 g/L.

22. The method of claim 18, wherein the pH controlling agent is one or more compounds selected from the group consisting of ammonia water, hydrochloric acid, and acetic acid.

23. The method of claim 18, wherein pH of the plating bath is 4-6.

24. The method of claim 18, wherein the plating bath further includes a complexing agent.

25. The method of claim 18, wherein the complexing agent is succinic acid and the succinic acid is added by 5-50 g/L.

26. The method of claim 18, wherein a temperature of the plating bath is 60-90° C.

27. The method of claim 18, wherein the electroless plating is performed for 1-10 min.

28. The method of claim 18, wherein the first nickel layer has a thickness of 0.3-2 μm.

29. The method of claim 18, wherein the first nickel layer is added by 5-15 parts by weight with respect to 100 parts by weight of the total layers.
